(19) United States
(12) Patent Application Publication
(10) Pub. No.: US 2025/0259577 A1
(43) Pub. Date: Aug. 14, 2025

(54) DISPLAY PANEL INCLUDING TEST TRANSISTOR AND DEFECT DETECTION METHOD FOR DISPLAY PANEL

(71) Applicant: SAMSUNG ELECTRONICS CO., LTD., Suwon-si (KR)

(72) Inventors: Youngki JUNG, Suwon-si (KR); Wonkeun PARK, Suwon-si (KR); Donghwan KIM, Suwon-si (KR); Donghun LEE, Suwon-si (KR); Sungsoo KIM, Suwon-si (KR)

(73) Assignee: SAMSUNG ELECTRONICS CO., LTD., Suwon-si (KR)

(21) Appl. No.: 19/096,997

(22) Filed: Apr. 1, 2025

Related U.S. Application Data
(63) Continuation of application No. PCT/KR2023/016906, filed on Oct. 27, 2023.

(30) Foreign Application Priority Data
Dec. 23, 2022 (KR) 10-2022-0183116

(51) Int. Cl. G09G 3/00; G09G 3/32; H10H 29/32; H10H 29/49

(52) U.S. Cl. CPC G09G 3/006; G09G 3/32; H10H 29/32; H10H 29/49; G09G 2330/12

(57) ABSTRACT

A display panel includes a plurality of pixel circuits configured to drive a plurality of inorganic light-emitting elements; a plurality of pixel electrodes configured to connect the plurality of inorganic light-emitting elements to the plurality of pixel circuits; a plurality of test transistors connected to the plurality of pixel circuits through the plurality of pixel electrodes; and at least one processor configured to: apply a voltage to at least one of the plurality of pixel circuits; and detect whether at least one of the plurality of pixel electrodes is defective based on current flowing through one of the plurality of test transistors according to the voltage applied to the at least one of the plurality of pixel circuits.

### CROSS-REFERENCE TO RELATED APPLICATIONS

This application is a continuation application of International Application No. PCT/KR2023/016906, filed on Oct. 27, 2023, in the Korean Intellectual Property Receiving Office, which claims priority to Korean Patent Application No. 10-2022-0183116, filed on Dec. 23, 2022, in the Korean Intellectual Property Office, the disclosures of which are incorporated by reference herein in their entireties.

### BACKGROUND

### 1. Field

The disclosure relates to a display panel and a method for detecting defects for the display panel.

### 2. Description of Related Art

With recent advances in technology, various types of display devices are being developed. One of them is the micro light emitting diode (“LED”) display device in which a plurality of micro LEDs are used to form a single pixel and these pixels are arranged in a matrix form.

Meanwhile, the micro LED display device is manufactured by mounting tens of thousands to tens of millions of micro LEDs at a dense interval. However, if the micro LEDs do not perform their functions due to a defect, the process efficiency is greatly reduced.

### SUMMARY

According to an aspect of the disclosure, a display panel includes: a plurality of pixel circuits configured to drive a plurality of inorganic light-emitting elements; a plurality of pixel electrodes configured to connect the plurality of inorganic light-emitting elements to the plurality of pixel circuits; a plurality of test transistors connected to the plurality of pixel circuits through the plurality of pixel electrodes; and at least one processor configured to: apply a voltage to at least one of the plurality of pixel circuits; and detect whether at least one of the plurality of pixel electrodes is defective based on current flowing through one of the plurality of test transistors according to the voltage applied to the at least one of the plurality of pixel circuits.

The display panel may further include a plurality of metal layers including: a first metal layer and a second metal layer on which the plurality of pixel circuits and the plurality of test transistors may be formed; a third metal layer on which a driving electrode for supplying a driving voltage to the plurality of pixel circuits may be formed; and a fourth metal layer on which a ground electrode for supplying a ground voltage to the plurality of pixel circuits may be formed. The plurality of pixel electrodes may be formed on the fourth metal layer.

Each of the plurality of pixel electrodes may include: a cathode pad connected to the ground electrode; and an anode pad connected to a pixel circuit of the plurality of pixel circuits.

A pixel circuit of the plurality of pixel circuits may be connected to the anode pad through a first via. A test transistor of the plurality of test transistors may be connected to the anode pad through a second via.

The plurality of inorganic light-emitting elements may be mounted on the display panel such that a cathode terminal of an inorganic light-emitting element is connected to the cathode terminal and an anode terminal of the inorganic light-emitting element is connected to the anode pad.

Based on the anode pad being opened or a connection wiring between the pixel circuit and the anode pad through the first via being disconnected, current may not flow through the test transistor in a state in which the voltage is applied to the pixel circuit during a defect test.

According to another aspect of disclosure, a method for detecting a defect of a display panel including a plurality of pixel circuits configured to drive a plurality of inorganic light emitting elements, a plurality of pixel electrodes configured to connect a plurality of inorganic light-emitting element to the plurality of pixel circuits, and a plurality of test transistors provided connected to the plurality of pixel circuits through the plurality of pixel electrodes, includes: applying a voltage to at least one of the plurality of pixel circuits; and detecting whether at least one of the plurality of pixel electrodes is defective based on a current flowing through the one of the plurality of test transistors according to the voltage.

Each of the plurality of pixel electrodes may include an anode pad to which a test transistor of the plurality of test transistors is connected. The detecting may include, based on current not flowing through the test transistor according to the voltage, detecting that the anode pad is defective.

Based on the anode pad being opened or a connection wiring between a pixel circuit of the plurality of pixel circuits and the anode pad through a via being disconnected, current may not flow through the test transistor in a state in which the voltage is applied to the pixel circuit during a defect test.

The display panel may further include a plurality of metal layers. The plurality of metal layers may include a first metal layer and a second metal layer on which the plurality of pixel circuits and the plurality of test transistors may be formed, a third metal layer on which a driving electrode for supplying a driving voltage to the plurality of pixel circuits may be formed, and a fourth metal layer on which a ground electrode for supplying a ground voltage to the plurality of pixel circuits may be formed. The plurality of pixel electrodes may be formed on the fourth metal layer.

A pixel circuit of the plurality of pixel circuits may be connected to the anode pad through a first via. The test transistor of the plurality of test transistors may be connected to the anode pad through a second via.

### BRIEF DESCRIPTION OF DRAWINGS

The above and other aspects, features, and advantages of certain embodiments of the present disclosure will be more apparent from the following detailed description, taken in conjunction with the accompanying drawings, in which:

FIG. 1 is a view of a display panel according to one or more embodiments;

FIG. 2 is a stack structure of metal layers according to one or more embodiments;

FIG. 3 is a block diagram of an inspection device according to one or more embodiments;

FIG. 4 is a flowchart of a method for detecting a defect of a display panel according to one or more embodiments;

FIG. 5 is a view of a display panel according to one or more embodiments; and

FIG. 6 is a view of a display module according to one or more embodiments.

### DETAILED DESCRIPTION

The embodiments of the present disclosure may be modified in various ways, and may have various embodiments, so specific embodiments are illustrated in the drawings and described in detail in the detailed description. However, it is to be understood that the disclosure is not limited to specific exemplary embodiments, but include all modifications, equivalents, and/or alternatives according to exemplary embodiments of the disclosure. Throughout the description of the accompanying drawings, similar components may be denoted by similar reference numerals.

In describing the disclosure, when it is decided that a detailed description for the known functions or configurations related to the disclosure may unnecessarily obscure the gist of the disclosure, the detailed description therefor will be omitted.

In addition, the following exemplary embodiments may be modified in several different forms, and the scope of the technical spirit of the disclosure is not limited to the following exemplary embodiments. Rather, these exemplary embodiments make the disclosure thorough and complete, and are provided to completely transfer the spirit of the disclosure to those skilled in the art.

Terms used in the disclosure are used only to describe specific exemplary embodiments rather than limiting the scope of the disclosure. Singular forms are intended to include plural forms unless the context clearly indicates otherwise.

In the disclosure, the expressions “have”, “may have”, “include” or “may include” used herein indicate existence of corresponding features (e.g., elements such as numeric values, functions, operations, or components), but do not exclude presence of additional features.

In the disclosure, the expressions “A or B”, “at least one of A or/and B”, or “one or more of A or/and B”, and the like may include any and all combinations of one or more of the items listed together. For example, the term “A or B”, “at least one of A and B”, or “at least one of A or B” may refer to all of the case (1) where only A is included, the case (2) where only B is included, or the case (3) where both A and B are included.

Expressions “first”, “second”, “1st,” “2nd,” or the like, used in the disclosure may indicate various components regardless of sequence and/or importance of the components, will be used only in order to distinguish one component from the other components, and do not limit the corresponding components.

When it is described that an element (e.g., a first element) is referred to as being “(operatively or communicatively) coupled with/to” or “connected to” another element (e.g., a second element), it should be understood that it may be directly coupled with/to or connected to the other element, or they may be coupled with/to or connected to each other through an intervening element (e.g., a third element).

On the other hand, when an element (e.g., a first element) is referred to as being “directly coupled with/to” or “directly connected to” another element (e.g., a second element), it should be understood that there is no intervening element (e.g., a third element) in-between.

An expression “˜configured (or set) to” used in the disclosure may be replaced by an expression, for example, “suitable for,” “having the capacity to,” “˜designed to,” “˜adapted to,” “˜made to,” or “˜capable of” depending on a situation. A term “˜configured (or set) to” may not necessarily mean “specifically designed to” in hardware.

Instead, an expression “˜an apparatus configured to” may mean that an apparatus “is capable of” together with other apparatuses or components. For example, a “processor configured (or set) to perform A, B, and C” may mean a dedicated processor (e.g., an embedded processor) for performing the corresponding operations or a generic-purpose processor (e.g., a central processing unit (CPU) or an application processor) that may perform the corresponding operations by executing one or more software programs stored in a memory device.

In exemplary embodiments, a ‘module’ or a ‘unit’ may perform at least one function or operation, and be implemented as hardware or software or be implemented as a combination of hardware and software. In addition, a plurality of ‘modules’ or a plurality of ‘units’ may be integrated into at least one module and be implemented as at least one processor except for a ‘module’ or a ‘unit’ that needs to be implemented as specific hardware.

Meanwhile, various elements and regions in the drawings are schematically drawn in the drawings. Therefore, the technical concept of the disclosure is not limited by a relative size or spacing drawn in the accompanying drawings.

Hereinafter, one or more embodiments according to the present disclosure will be described in detail with reference to the accompanying drawings so that a person with ordinary knowledge in the technical field to which the present disclosure belongs can easily implement the present disclosure.

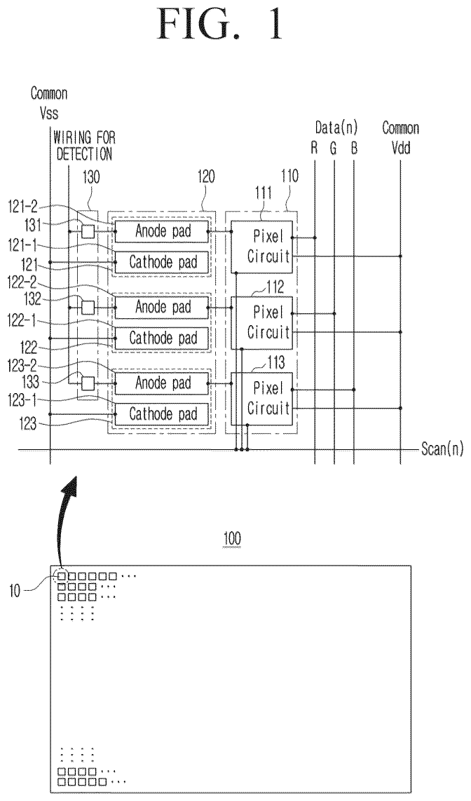

FIG. 1 is a view provided to explain a display panel according to one or more embodiments.

Referring to FIG. 1, a display panel 100 may include a plurality of pixel circuits 110.

Specifically, the display panel 100 may include a pixel array in which a plurality of pixels 10 are arranged in a matrix form.

Each pixel 10 may include the plurality of pixel circuits 110 for driving a plurality of inorganic light-emitting elements that constitute a plurality of subpixels. For example, the plurality of subpixels may include three types of subpixels, such as a red (R) subpixel, a green (G) subpixel, and a blue (B) subpixel.

A pixel circuit is a circuit for driving an inorganic light-emitting element mounted (or disposed) on the display panel 100. The pixel circuit may be implemented with one or more thin film transistors (TFTs) (e.g., PMOS transistors) and one or more capacitors. The pixel circuit is arranged per subpixel, and may therefore be referred to as a subpixel circuit.

For example, the plurality of pixel circuits 110 may include a pixel circuit 111 for driving an R inorganic light-emitting element corresponding to an R subpixel, a pixel circuit 112 for driving a G inorganic light-emitting element corresponding to a G subpixel, and a pixel circuit 113 for driving a B inorganic light-emitting element corresponding to a B subpixel.

Here, the inorganic light-emitting element refers to a light-emitting element manufactured using inorganic materials, which is different from an Organic Light Emitting Diode (OLED) manufactured using organic materials. In particular, according to one or more embodiments, the inorganic light-emitting element may be a micro Light Emitting Diode (LED) (μ-LED) having a size of 100 micrometers (μm) or less. However, in various embodiments, the inorganic light-emitting element is not necessarily limited to a micro LED.

Further, the display panel 100 may include a pixel electrode 120. The pixel electrode 120 may be arranged per pixel circuit, and may connect a pixel circuit to an inorganic light-emitting element driven by the pixel circuit.

For example, each pixel 10 includes a pixel electrode 121 for connecting an inorganic light-emitting element (e.g., an R inorganic light-emitting element) mounted on the pixel electrode 121 to the pixel circuit 111, a pixel electrode 122 for connecting an inorganic light-emitting element (e.g., a G inorganic light-emitting element) mounted on the pixel electrode 122 to the pixel circuit 112, and a pixel electrode 123 for connecting an inorganic light-emitting element (e.g., a B inorganic light-emitting element) mounted on the pixel electrode 123 to the pixel circuit 113.

Each pixel electrode 120 may include a cathode pad and an anode pad. For example, the pixel electrodes 121, 122, and 123 may include cathode pads 121-1, 122-1, and 123-1 and anode pads 121-2, 122-2, and 123-2.

The cathode pads 121-1, 122-1, 123-1 may receive a ground voltage (Vss) input. Further, the anode pads 121-2, 122-2, 123-2 may be connected to the pixel circuits 111, 112, 113, respectively.

Each pixel circuit 110 may receive a driving voltage (Vdd). Further, each pixel circuit 110 may receive a scan signal through a scan line. When selected by the scan signal, each pixel circuit 110 may drive an inorganic light-emitting element mounted on the pixel electrode 120 using a data voltage applied through a data line.

For example, when a driving voltage is applied to the anode pad according to the driving of the pixel circuit, the pixel circuit may provide driving current to the inorganic light-emitting elements mounted on the pixel electrode using the data voltage.

To this end, the pixel circuit may include a PAM circuit for providing a driving current of a magnitude corresponding to a Pulse Amplified Modulation (PAM) data voltage to the inorganic light-emitting element and/or a Pulse Width Modulation (PWM) circuit for providing a driving current provided from the PAM circuit to the inorganic light-emitting element for a time corresponding to a PWM data voltage.

In addition, the display panel 100 may include a test transistor 130. The test transistors 130 may be used to check for defects in the pixel circuit 110 and the pixel electrode 120 (particularly, the anode pads 121-2, 122-2, 123-2).

To this end, the test transistor 130 is provided per pixel circuit, and is connected to the pixel circuit 110 through the pixel electrode 120.

Specifically, the test transistor 130 may be connected to the pixel circuit 110 through the anode pads 121-2, 122-2, 123-2.

For example, a test transistor 131 may be connected to the pixel circuit 111 via the anode pads 121-2, the test transistor 132 may be connected to the pixel circuit 112 via the anode pads 122-2, and the test transistor 133 may be connected to the pixel circuit 113 via the anode pads 123-2.

Further, the test transistor 130 may be connected to a detection wiring. Meanwhile, although FIG. 1 illustrates that the test transistors 131, 132, and 133 are connected through a single detection wiring, the present disclosure is not limited thereto. In other words, separate detection wiring may be provided for each of the test transistors 131, 132, and 133.

Meanwhile, the pixel circuit, the pixel electrode, and the test transistor may form a metal layer structure on a substrate. Here, the substrate may be implemented as glass, but is not limited thereto.

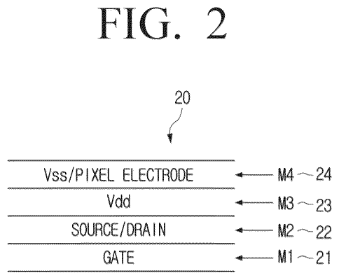

FIG. 2 is a view provided to explain a stack structure of metal layers according to one or more embodiments.

A plurality of metal layers 20 may include a first metal layer M1 (21), a second metal layer M2 (22), a third metal layer M3 (23), and a fourth metal layer M4 (24). The material forming the first to fourth metal layers M1 to M4 (210 to 240) may be a conductive metal.

The plurality of pixel circuits 110 and the test transistors 130 may be formed on the first metal layer M1 (21) and the second metal layer M2 (22).

For example, gate electrodes of transistors included in the plurality of pixel circuits 110 and gate electrodes of the test transistors 130 may be formed on the first metal layer M1 (21), and data electrodes (e.g., source electrodes and drain electrodes) of transistors included in the plurality of pixel circuits 110 and data electrodes of the test transistors 130 may be formed on the second metal layer M2 (22).

In addition, scan lines for providing scan signals to the plurality of pixel circuits 110 and data lines for providing data voltages to the plurality of pixel circuits 110 may be formed in the first metal layer M1 (21) and the second metal layer M2 (22).

A driving electrode for supplying a driving voltage (Vdd) to the plurality of pixel circuits 110 may be formed on the third metal layer M3 (23), and a ground electrode for supplying a ground voltage (Vss) to the plurality of pixel circuits 110 may be formed on the fourth metal layer M4 (24).

Further, the pixel electrode 120 may be formed on the fourth metal layer M4 (24). In other words, the cathode pads 121-1, 122-1, 123-1 and the anode pads 121-2, 122-2, 123-2 may be formed on the fourth metal layer M4 (24). Here, the cathode pads may be connected to the ground electrode, and the anode pads may be connected to the pixel circuit.

Different layers may be connected through a via. For example, the pixel circuit 110 may be connected to the driving electrode through a via. The pixel circuit 110 may be connected to the anode pads 121-2, 122-2, 123-2 through a via. In addition, the test transistor 130 may be connected to the anode pads 121-2, 122-2, 123-2 through a via.

Meanwhile, although the preceding examples describe that the plurality of metal layers consist of four metal layers, the present disclosure is not limited thereto, and the plurality of metal layers may include five metal layers.

For example, when separate driving voltages are applied to the PAM circuit and the PWM circuit, for example, a first driving voltage (Vdd_PAM) is applied to the PAM circuit and a second driving voltage (Vdd_PWM) is applied to the PWM circuit, one more metal layer may be required. For example, a driving electrode for supplying the first driving voltage (Vdd_PAM) may be formed on the third metal layer M3, and a driving electrode for supplying the second driving voltage (Vdd_PWM) may be formed on the fourth metal layer M4.

Further, the ground electrode and the pixel electrode 120 may be formed on the fifth metal layer M5.

Meanwhile, although the preceding examples describe that the transistor of the pixel circuit is implemented as a PMOS transistor, but the present disclosure is not limited thereto, and the transistor of the pixel circuit may be implemented as an NMOS transistor. In the case of such an NMOS pixel circuit, the test transistor may be connected through a cathode pad. In other words, the test transistor may be connected to the pixel circuit through a cathode pad.

Meanwhile, although not shown, the display panel 100 may include various circuits for driving a plurality of pixel circuits.

For example, the display panel 100 may include a scan driver circuit (or gate driver circuit) for providing a scan signal to the plurality of pixel circuits, a data driver circuit (or 9 source driver circuit) for providing a data voltage to the plurality of pixel circuits, a clock signal providing circuit for providing various clock signals to drive the scan driver or data driver circuit, a MUX circuit for selecting each of the subpixels constituting a pixel, and a driving voltage providing circuit for providing various driving voltages to the plurality of pixel circuits.

In this case, at least some of the various circuits described above may be formed on a plurality of metal layers with a plurality of pixel circuits.

Alternatively, at least some of the various circuits described above may be implemented in the form of a separate chip and mounted on an external Printed Circuit Board (PCB) together with a Timing Controller (TCON), and may be connected to a plurality of pixel circuits formed on the TFT layer of the display panel 100 through a Film On Glass (FOG) wiring.

Alternatively, at least some of the various circuits described above may be implemented in the form of a separate chip, disposed on a film in the form of a Chip On Film (COF), and connected to a plurality of pixel circuits formed on the TFT layer of the display panel 100 through a Film On Glass (FOG) wiring.

Alternatively, at least some of the various circuits described above may be implemented in the form of a separate chip, disposed in the form of a chip-on-glass (COG) (i.e., disposed on the back side of the glass substrate of the display panel 100 (on the side opposite to the side on which the TFT layer is formed with reference to the glass substrate)), and connected to a plurality of pixel circuits formed on the TFT layer of the display panel 100 through a connection wiring.

For example, among the various circuits described above, the scan driver circuit and the mux circuit may be formed on a plurality of metal layers, the data driver circuit may be disposed on the rear side of the substrate of the display panel 100, and the driving voltage supply circuit, the clock signal providing circuit, and the timing controller (TCON) may be disposed on an external printed circuit board (PCB), but are not limited thereto.

Meanwhile, when the anode pads 121-2, 122-2, 123-2 are open or the connection wiring through a via between the pixel circuits 111, 112, 113 and the anode pads 121-2, 122-2, 123-2 is disconnected, no current flows through the test transistors 131, 132, 133 even if a voltage is applied to the pixel circuits 111, 112, 113 for a defect test. This can be used to detect a defect in the pixel electrode 120, which will be described below in greater detail.

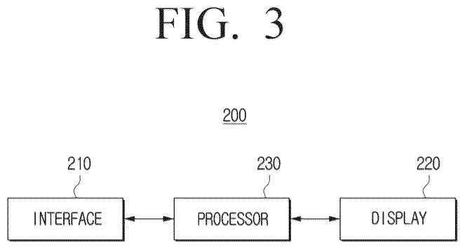

FIG. 3 is a block diagram provided to explain configuration of an inspection device according to one or more embodiments.

Referring to FIG. 3, an inspection device 200 may include an interface 210, a display 220, and a processor 230.

The interface 210 may be connected to the display panel 100. Specifically, the interface 210 may be connected to the display panel 100 to transmit and receive various signals.

The display 220 may display an image. To this end, the display 220 may be implemented as various types of displays such as LCDs, LEDs, or OLEDs.

The processor 230 controls the overall operations of the inspection device 200. Specifically, the processor 230 may be connected to each configuration of the inspection device 200 to control the overall operations of the inspection device 200. For example, the processor 230 may be connected to the interface 210 and the display 220 to control the inspection device 200. The processor 230 may drive an operating system or an application program to control hardware or software components connected to the processor 230, and may perform various data processing and computations. Further, the processor 230 may load instructions or data received from at least one of the other components into volatile memory for processing, and may store various data in non-volatile memory.

To this end, the processor 230 may be implemented as a dedicated processor (e.g., embedded processor) for performing the corresponding operations or as a generic-purpose processor (e.g., central processing unit (CPU), graphics processing unit (GPU), or application processor (AP)) capable of performing the corresponding operations by executing one or more software programs stored in the memory.

The processor 230 may check for defects in the display panel 100 connected through the interface 210.

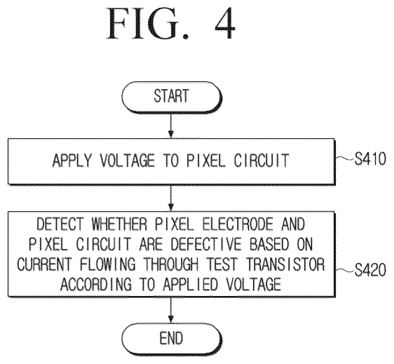

FIG. 4 is a flowchart provided to explain a method for detecting a defect of a display panel according to one or more embodiments.

The processor 230 applies a voltage to the pixel circuit (S410). Here, the voltage may be a data voltage.

For example, the processor 230 may transmit data signals and various control signals to the display panel 100 through the interface 210 for a defect test of the pixel circuit to be inspected. In this case, the scan driver circuit of the display panel 100 may provide a scan signal to the pixel circuit 111, and the data driver circuit of the display panel 100 may apply a data voltage corresponding to the data signal to the pixel circuit selected by the scan signal. Further, a driving voltage may be applied to the pixel circuit.

Subsequently, the processor 230 detects whether the pixel electrode is defective based on the current flowing through the test transistor according to the applied voltage (S420).

Here, the pixel electrode may include an anode pad to which a test transistor is connected. When no current flows through the test transistor according to the applied voltage, the processor 230 may detect that the anode pad is defective.

Specifically, the interface 210 is connected to the detection wiring of the test transistor, and may receive current from the test transistor via the detection wiring.

In this case, when the anode pad is open or the connection wiring between the pixel circuit and the anode pad is disconnected, current may not flow through the test transistor even if a data voltage is applied to the pixel circuit during a defect test.

In addition, when the pixel circuit is defective, current of a magnitude different from the magnitude corresponding to the data voltage applied to the pixel circuit during the defect test may flow through the test transistor, or no current may flow through the test transistor.

Accordingly, the processor 230 may identify whether the pixel circuit and the anode pad are defective based on whether current flows through the test transistor and, if current flows through the test transistor, the magnitude of the current received from the test transistor.

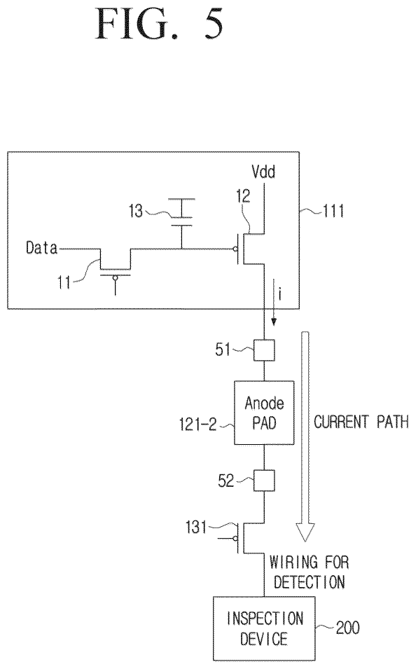

FIG. 5 is a view provided to explain a method for detecting a defect of a display panel according to one or more embodiments. In FIG. 5, it is assumed that the pixel circuit 111 is a pixel circuit to be inspected for defects. Since FIG. 5 is a view provided to explain a method for detecting whether there is a defect using a test transistor, an example of a part of the structure of the pixel circuit 111 is illustrated.

Referring to FIG. 5, the display panel 100 may be operated by various control signals received from the inspection device 200.

Specifically, the display panel 100 may apply a gate signal to a gate terminal of a transistor 11 of the pixel circuit 111 to turn on the transistor 11, and may apply a data voltage to the transistor 11. The data voltage may be charged to a capacitor 13 through the transistor 11.

Subsequently, the display panel 100 may apply a gate signal to a gate terminal of the test transistor 131 to turn on the test transistor 131. When the test transistor 131 is turned on, current (i) may flow through a transistor 12 based on the data voltage applied to the gate terminal of the transistor 12 by the capacitor 13.

In this case, when the pixel circuit 111 is operating normally, current of a specific magnitude determined by the data voltage may flow through the transistor 12. However, when the pixel circuit 111 is defective, current of a different magnitude may flow through the transistor 12, or no current may flow through the transistor 12.

Meanwhile, since the test transistor 131 is connected to the inspection device 200 through the detection wiring, when the test transistor 131 is turned on, a current path is formed between the pixel circuit 111 and the inspection device 200, and the current flowing through the transistor 12 may be provided to the inspection device 200 through the current path.

Thus, the processor 230 may use the magnitude of the current (i) provided by the pixel circuit 111 to detect whether the pixel circuit 111 is operating normally.

For example, when current of a specific magnitude determined by the data voltage flows, the processor 230 may detect that the pixel circuit 111 is operating normally. When current of a magnitude different from the specified magnitude flows or no current flows, the processor 230 may detect that the pixel circuit 111 is defective.

Meanwhile, the pixel circuit 111 and the inspection device 200 may be connected through a connection wiring 51, the anode pad 121-2, a connection wiring 52, and the test transistor 131. Here, the connection wiring 51 may be a wiring connecting the pixel circuit 111 and the anode pads 121-2 through a via, and the connection wiring 52 may be a wiring connecting the anode pads 121-2 and the test transistor 131 through a via.

In this case, when the anode pad 121-2 is open or the connection wiring 51 between the pixel circuit 111 and the anode pads 121-2 is disconnected, no current will flow.

Accordingly, when no current flows, the processor 230 may detect that the anode pad 121-2 is defective. Here, the defective anode pad 121-2 may include the case where the anode pad 121-2 is open or the connection wiring 51 is disconnected.

The processor 230 may display information about the inspection results of the display panel 100 on the display 220. For example, the processor 230 may display information such as whether a defect is detected, the location of the pixel (or subpixel) where a defect is detected, etc. on the display 220.

Meanwhile, in the process of manufacturing a micro LED display, before bonding the micro LED to a substrate, a process is required to inspect whether the TFT and wiring of the substrate are formed normally. Such an inspection process may be performed through pattern inspection (e.g. AOI) and electrical inspection.

In this case, since the cathode pad is formed on the same metal layer as the ground electrode, whether there is a defect on the cathode pad can be easily detected through pattern inspection. However, in the case of the anode pad, it is difficult to detect a defect using pattern inspection alone because it is necessary to inspect the connection wiring between the pixel circuit formed on the lower metal layer and the anode pad formed on the upper metal layer. In addition, since electrical inspection only inspects the electrical characteristics of the TFT circuit formed on the lower metal layer, it is not possible to detect the characteristics of the anode pad itself (e.g., openness of the anode pad).

However, according to the present disclosure, a test transistor connected to the pixel circuit through the anode pad can be used to detect whether the anode pad and/or the connection wiring between the pixel circuit and the anode pad is defective. Accordingly, it is possible to prevent an off-dot problem that may occur when the micro LED does not emit light after the micro LED is bonded to the substrate.

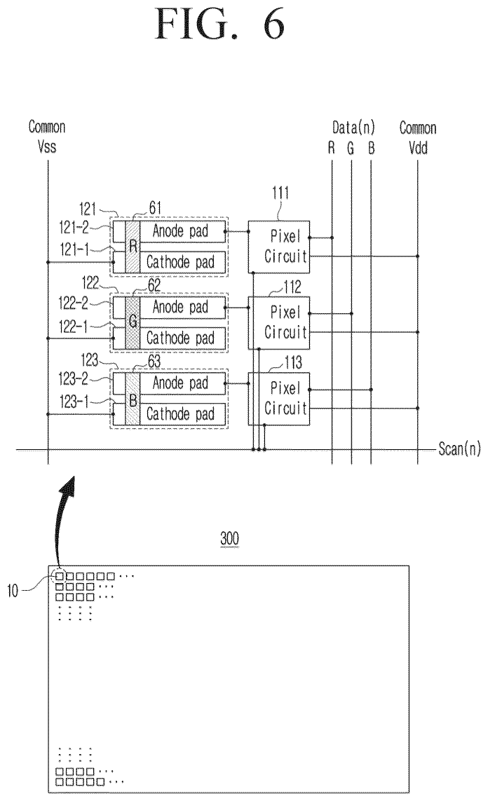

FIG. 6 is a view provided to explain a display module according to one or more embodiments.

In FIG. 6, description of contents that overlap with the above-described contents related to the display panel 100 will be omitted.

Referring to FIG. 6, when a plurality of inorganic light-emitting elements are mounted on the display panel 100 through a transfer and bonding process, a display module 300 in which each subpixel includes an inorganic light-emitting element may be manufactured.

In this case, the plurality of inorganic light-emitting elements may be mounted on the display panel 100 such that the cathode terminal of the inorganic light-emitting element is connected to the cathode pad and the anode terminal of the inorganic light-emitting element is connected to the anode pad.

For example, an R inorganic light-emitting element 61 corresponding to an R subpixel may be mounted on the pixel electrode 121 connected to the pixel circuit 111. In this case, the cathode terminal of the R inorganic light-emitting element 61 may be connected to the cathode electrode 121-1, and the anode terminal of the R inorganic light-emitting element 61 may be connected to the anode electrode 121-2.

In addition, a G inorganic light-emitting element 62 corresponding to a G subpixel may be mounted on the pixel electrode 122 connected to the pixel circuit 112. In this case, the cathode terminal of the G inorganic light-emitting element 62 may be connected to the cathode electrode 122-1, and the anode terminal of the G inorganic light-emitting element 62 may be connected to the anode electrode 122-2.

Further, a B inorganic light-emitting element 63 corresponding to a B subpixel may be mounted on the pixel electrode 123 connected to the pixel circuit 113. In this case, the cathode terminal of the B inorganic light-emitting element 63 may be connected to the cathode electrode 123-1, and the anode terminal of the B inorganic light-emitting element 63 may be connected to the anode electrode 123-2.

As described above, the inorganic light-emitting element may be a micro-LED. Accordingly, the display module 300 becomes a micro LED display module in which each subpixel is implemented as a micro LED. The micro LED display module is composed of a plurality of inorganic LEDs, each of which is 100 micrometers or less.

The micro LED display module offers better contrast, response time, and energy efficiency compared to a liquid crystal display (LCD) panel that requires backlighting. Meanwhile, while both organic light-emitting diodes (organic LEDs, OLEDs) and micro LEDs are energy efficient, micro LEDs can offer better performance than OLEDs in terms of brightness, luminous efficiency, and lifespan.

Meanwhile, according to one or more embodiments, the above-described various embodiments may be implemented as software including instructions stored in machine-readable storage media, which can be read by machine (e.g.: computer). The machine may be a device that invokes the stored instruction from the storage medium and can be operated based on the invoked instruction, and may include a device (e.g., electronic device A) according to the embodiments disclosed herein. In case that the instruction is executed by the processor, the processor may directly perform a function corresponding to the instruction or other components may perform the function corresponding to the instruction under control of the processor. The instruction may include codes generated or executed by a compiler or an interpreter. The machine-readable storage media may be provided in a non-transitory storage medium. Here, ‘non-transitory storage medium’ merely means that the storage medium is tangible without including a signal (e.g. electromagnetic waves), and does not distinguish whether data are semi-permanently or temporarily stored in the storage medium.

In addition, according to one or more embodiments, the methods according to one or more embodiments may be included and provided in a computer program product. The computer program product may be traded as a product between a seller and a purchaser. The computer program product may be distributed in the form of a storage medium (e.g., compact disc read only memory (CD-ROM)) that is readable by devices, or may be distributed online through an application store (e.g., PlayStore™). In the case of an online distribution, at least part of the computer program product may be at least temporarily stored in a storage medium readable by a machine such as a server of the manufacturer, a server of an application store, or the memory of a relay server or may be temporarily generated.

Further, the above-described various embodiments may be implemented in a recording medium that can be read by a computer or a similar device using software, hardware, or a combination thereof. In some cases, embodiments described herein may be implemented by a processor itself. According to software implementation, embodiments such as procedures and functions described in this specification may be implemented as separate software. Each software may perform one or more functions and operations described in this disclosure.

Meanwhile, computer instructions for performing processing operations of a device according to the above-described various embodiments may be stored in a non-transitory computer-readable medium. When being executed by a processor of a specific device, the computer instructions stored in such a non-transitory computer-readable medium allows the specific device to perform processing operations in the device according to the above-described various embodiments. The non-transitory computer-readable medium refers to a medium that stores data semi-permanently and can be read by a device, rather than a medium that stores data for a short period of time, such as registers, caches, memory, etc. Specific examples of the non-transitory computer-readable medium may include CD, DVD, hard disk, Blu-ray disk, USB, memory card, ROM, etc.

Further, the components (e.g., modules or programs) according to various embodiments described above may include a single entity or a plurality of entities, and some of the corresponding sub-components described above may be omitted or other sub-components may be further included in the various embodiments. Alternatively or additionally, some components (e.g., modules or programs) may be integrated into one entity and perform the same or similar functions performed by each corresponding component prior to integration. Operations performed by the modules, the programs, or the other components according to the various embodiments may be executed in a sequential manner, a parallel manner, an iterative manner, or a heuristic manner, or at least some of the operations may be performed in a different order or be omitted, or other operations may be added.

While various embodiments have been described above with reference to the drawings, the present disclosure is not limited thereto, and any combination or substitution of components as appropriate is included within the scope of the present disclosure. In some embodiments, modifications such as combinations, changes in the order of processes, and various changes in design may be made on the basis of knowledge of a person skilled in the art, and such modified embodiments are within the scope of the present disclosure and the appended claims.

What is claimed is:

1. A display panel comprising:
a plurality of pixel circuits configured to drive a plurality of inorganic light-emitting elements;
a plurality of pixel electrodes configured to connect the plurality of inorganic light-emitting elements to the plurality of pixel circuits;
a plurality of test transistors connected to the plurality of pixel circuits through the plurality of pixel electrodes; and
at least one processor configured to:
apply a voltage to at least one of the plurality of pixel circuits; and
detect whether at least one of the plurality of pixel electrodes is defective based on current flowing through one of the plurality of test transistors according to the voltage applied to the at least one of the plurality of pixel circuits.

2. The display panel as claimed in claim 1, further comprising: a plurality of metal layers comprising:
a first metal layer and a second metal layer on which the plurality of pixel circuits and the plurality of test transistors are formed;
a third metal layer on which a driving electrode for supplying a driving voltage to the plurality of pixel circuits is formed; and
a fourth metal layer on which a ground electrode for supplying a ground voltage to the plurality of pixel circuits is formed, and
wherein the plurality of pixel electrodes are formed on the fourth metal layer.

3. The display panel as claimed in claim 2, wherein each of the plurality of pixel electrodes comprise:
a cathode pad connected to the ground electrode; and
an anode pad connected to a pixel circuit of the plurality of pixel circuits.

4. The display panel as claimed in claim 3, wherein the pixel circuit of the plurality of pixel circuits is connected to the anode pad through a first via; and
wherein a test transistor of the plurality of test transistors is connected to the anode pad through a second via.

5. The display panel as claimed in claim 4, wherein the plurality of inorganic light-emitting elements are mounted on the display panel such that a cathode terminal of an inorganic light-emitting element is connected to the cathode terminal and an anode terminal of the inorganic light-emitting element is connected to the anode pad.

6. The display panel as claimed in claim 4, wherein, based on the anode pad being opened or a connection wiring between the pixel circuit and the anode pad through the first via being disconnected, no current flows through the test transistor in a state in which the voltage is applied to the pixel circuit during a defect test.

7. A method for detecting a defect of a display panel including a plurality of pixel circuits configured to drive a plurality of inorganic light emitting elements, a plurality of pixel electrodes configured to connect a plurality of inorganic light-emitting element to the plurality of pixel circuits, and a plurality of test transistors provided connected to the plurality of pixel circuits through the plurality of pixel electrodes, comprising:
applying a voltage to at least one of the plurality of pixel circuits; and
detecting whether at least one of the plurality of pixel electrodes is defective based on a current flowing through the one of the plurality of test transistors according to the voltage.

8. The method as claimed in claim 7, wherein each of the plurality of pixel electrodes comprise an anode pad to which a test transistor of the plurality of test transistors is connected, and
wherein the detecting comprises, based on no current flowing through the test transistor according to the voltage, detecting that the anode pad is defective.

9. The method as claimed in claim 8, wherein, based on the anode pad being opened or a connection wiring between a pixel circuit of the plurality of pixel circuits and the anode pad through a via being disconnected, no current flows through the test transistor in a state in which the voltage is applied to the pixel circuit during a defect test.

10. The method as claimed in claim 7, wherein the display panel further comprises a plurality of metal layers,
wherein the plurality of metal layers include a first metal layer and a second metal layer on which the plurality of pixel circuits and the plurality of test transistors are formed, a third metal layer on which a driving electrode for supplying a driving voltage to the plurality of pixel circuits is formed, and a fourth metal layer on which a ground electrode for supplying a ground voltage to the plurality of pixel circuits is formed, and
wherein the plurality of pixel electrodes are formed on the fourth metal layer.

11. The method as claimed in claim 8, wherein a pixel circuit of the plurality of pixel circuits is connected to the anode pad through a first via; and
wherein the test transistor of the plurality of test transistors is connected to the anode pad through a second via.
